(19) United States
(12) Patent Application Publication
(10) Pub. No.: US 2026/0271599 A1
(43) Pub. Date: Sep. 10, 2026

(54) DISPLAY DEVICE AND ELECTRONIC DEVICE COMPRISING THE SAME

(71) Applicant: Samsung Display Co., Ltd., Yongin-si (KR)

(72) Inventors: Dae Ho KIM, Yongin-si (KR); Sang Seop KUM, Yongin-si (KR); HOICK CHO, Yongin-si (KR)

(21) Appl. No.: 19/318,250

(22) Filed: Sep. 3, 2025

(30) Foreign Application Priority Data
Mar. 6, 2025 (KR) 10-2025-0028909

(51) Int. Cl. H10K 59/80; H10K 59/131; H10K 59/38; H10K 59/40; H10K 102/00

(52) U.S. Cl. CPC H10K 59/8792; H10K 59/131; H10K 59/38; H10K 59/40; H10K 2102/311

(57) ABSTRACT

A display device includes: a substrate including a display area and a non-display area surrounding the display area, a first dam and a second dam in the non-display area, a conductive pattern between the first dam and the second dam, and a light blocking layer on the first dam and the second dam, wherein the conductive pattern includes an opening pattern between the first dam and the second dam, the light blocking layer includes a light blocking opening between the first dam and the second dam, and the opening pattern and the light blocking opening overlap.

### CROSS-REFERENCE TO RELATED APPLICATIONS

The present application claims priority to and the benefit of Korean Patent Application No. 10-2025-0028909, filed on Mar. 6, 2025, the entire content of which is incorporated herein by reference.

### BACKGROUND

### 1. Field

Aspects of some embodiments of the present disclosure relate to a display device and an electronic device comprising the same.

### 2. Description of the Related Art

A display device is a device for displaying images and includes a Liquid Crystal Display (LCD), an Organic Light Emitting Diode (OLED) Display, and the like. Such display devices are used in various electronic devices such as mobile phones, navigation systems, digital cameras, electronic books, portable game machines, or various terminals.

A display device such as an organic light emitting display device may have a structure in which the display device may be bent or folded by using a flexible substrate.

The above information disclosed in this Background section is only for enhancement of understanding of the background and therefore the information discussed in this Background section does not necessarily constitute prior art.

### SUMMARY

Aspects of some embodiments of the present disclosure include a display device having a relatively flat upper portion by compensating for a step difference in an opening pattern functioning as an alignment mark, and an electronic device comprising the same.

A display device according to some embodiments includes a substrate including a display area and a non-display area surrounding the display area, a first dam and a second dam in the non-display area, a conductive pattern positioned between the first dam and the second dam, and a light blocking layer positioned on the first dam and the second dam, wherein the conductive pattern includes an opening pattern positioned between the first dam and the second dam, the light blocking layer includes a light blocking opening positioned between the first dam and the second dam, and the opening pattern and the light blocking opening overlap.

According to some embodiments, the opening pattern may be spaced apart from the first dam and the second dam.

According to some embodiments, the light blocking opening may be spaced apart from the first dam and the second dam.

According to some embodiments, the light blocking opening may overlap with at least a portion of the conductive pattern.

According to some embodiments, the light blocking opening may surround the opening pattern.

According to some embodiments, the light blocking layer may overlap with the first dam and the second dam.

According to some embodiments, the display device may further include a second conductive pattern positioned between the first dam and the display area.

According to some embodiments, the display device may further include an overcoat layer positioned on the light blocking layer, and the overcoat layer may overlap with the opening pattern.

According to some embodiments, the overcoat layer may fill a valley positioned between the first dam and the second dam.

According to some embodiments, the light blocking layer may include at least two color filters.

According to some embodiments, the color filter includes a red color filter and a blue color filter, and the red color filter may cover the blue color filter.

A display device according to some embodiments includes a substrate including a display area and a non-display area surrounding the display area, a first dam and a second dam in the non-display area, a conductive pattern positioned between the first dam and the second dam, a first overcoat layer positioned on the first dam and the second dam, and a first touch organic layer positioned on the first overcoat layer, wherein the conductive pattern includes an opening pattern positioned between the first dam and the second dam, and the first overcoat layer and the first touch organic layer may overlap with a valley between the first dam and the second dam.

According to some embodiments, the display area includes a transistor positioned on the substrate, a light emitting device electrically connected to the transistor, an encapsulation layer positioned on the light emitting device, a sensing electrode positioned on the encapsulation layer, and a color filter positioned on the sensing electrode, and the first overcoat layer may be positioned on the color filter.

According to some embodiments, the display device may further include a light blocking layer positioned on the first touch organic layer, and a second overcoat layer positioned on the light blocking layer.

According to some embodiments, the second overcoat layer extends to the non-display area and may overlap with the valley.

According to some embodiments, the light blocking layer extends to the non-display area and may be spaced apart from the valley.

According to some embodiments, the first touch organic layer may have a flat upper surface.

An electronic device according to some embodiments includes a display device, wherein the display device includes a substrate including a display area and a non-display area surrounding the display area, a first dam and a second dam in the non-display area, a conductive pattern positioned between the first dam and the second dam, and a light blocking layer positioned on the first dam and the second dam, wherein the conductive pattern includes an opening pattern positioned between the first dam and the second dam, the light blocking layer includes a light blocking opening positioned between the first dam and the second dam, and the opening pattern and the light blocking opening may overlap.

According to some embodiments, the display device may further include an overcoat layer positioned on the light blocking layer, and the overcoat layer may overlap with the opening pattern.

According to some embodiments, the electronic device may further include a protection layer and a cover window positioned on the overcoat layer.

According to some embodiments, a display device having a relatively flat upper portion by compensating for a step difference in an opening pattern functioning as an alignment mark, and an electronic device comprising the same can be provided.

### BRIEF DESCRIPTION OF THE DRAWINGS

FIG. 1 is a block diagram of an electronic device according to some embodiments.

FIG. 2 shows schematic diagrams of electronic devices according to some embodiments.

FIG. 3 is a schematic perspective view showing a usage state of an electronic device according to some embodiments.

FIG. 4 is an exploded perspective view of an electronic device according to some embodiments.

FIG. 5 is a perspective view schematically showing an electronic device according to some embodiments.

FIG. 6A is a plan view of a display panel according to some embodiments.

FIG. 6B is a plan view showing conductive patterns in a display panel according to some embodiments.

FIG. 7 is a cross-sectional view of a display panel corresponding to a display area.

FIG. 8 is a plan view of a portion of a non-display area.

FIG. 9 is a cross-sectional view taken along the line A-A′ of FIG. 8.

FIG. 10 is a cross-sectional view taken along the line B-B′ of FIG. 8.

FIG. 11 is a cross-sectional view showing a portion of a non-display area according to some embodiments.

FIGS. 12 and 13 are cross-sectional views of a non-display area according to some embodiments, respectively.

FIG. 14 is a cross-sectional view of a display area according to some embodiments.

FIGS. 15 and 16 are cross-sectional views of a non-display area according to some embodiments, respectively.

FIG. 17 is an experimental image of a display panel according to some embodiments.

FIG. 18 is an experimental image of a display panel according to a comparative example.

FIG. 19 is an image of a display panel according to some embodiments.

### DETAILED DESCRIPTION

Hereinafter, aspects of some embodiments of the present disclosure will be described in more detail with reference to the accompanying drawings so that those skilled in the art can easily practice the disclosure. Embodiments according to the present disclosure may be implemented in various different forms and are not limited to the specific embodiments described herein.

To more clearly describe aspects of some embodiments of the present disclosure, description of some parts unrelated to the description may be omitted, and the same reference numerals are assigned to the same or similar components throughout the specification.

In addition, the size and thickness of each component shown in the drawings are arbitrarily shown for convenience of description, so the present disclosure is not necessarily limited to what is shown. In the drawings, thicknesses are enlarged to clearly express various layers and regions. And in the drawings, for convenience of description, the thicknesses of some layers and regions are exaggerated.

In addition, in case that a part such as a layer, film, region, plate, or the like is said to be “on” or “above” another part, this includes not only the case that it is “directly on” another part, but also the case that there is another part in between. Conversely, in case that a part is said to be “directly on” another part, it means that there is no other part in between. In addition, being “on” or “above” a reference part means being positioned above or below the reference part, and does not necessarily mean being positioned “on” or “above” in the direction opposite to gravity.

In addition, throughout the specification, in case that a part is said to “include” a certain component, this means that it may further include other components rather than excluding other components unless there is a statement to the contrary.

In addition, throughout the specification, “in plan view” means the case that the target part is viewed from above, and “in cross-section” means the case that a cross-section obtained by vertically cutting the target part is viewed from the side.

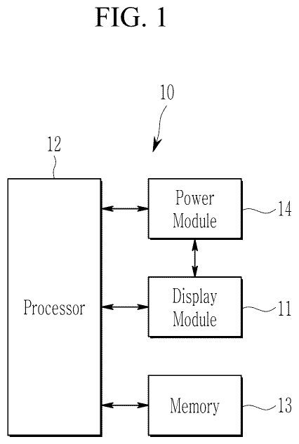

FIG. 1 is a block diagram of an electronic device according to some embodiments.

Referring to FIG. 1, an electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information necessary for operation of the processor 12 or the display module 11 may be stored in the memory 13. In case that the processor 12 executes an application stored in the memory 13, video data signals and/or input control signals are transmitted to the display module 11, and the display module 11 may process the provided signals to output video information through a display screen.

The power module 14 may include a power supply module such as a power adapter or a battery device, and a power conversion module which converts power supplied by the power supply module to generate power necessary for operation of the electronic device 10.

At least one of the components of the electronic device 10 described above may be included in the display device according to the embodiments described above. In addition, some of the individual modules functionally included in one module may be included in the display device and others may be provided separately from the display device. For example, the display device may include the display module 11, and the processor 12, memory 13, and power module 14 may be provided in the form of other devices in the electronic device 10 other than the display device.

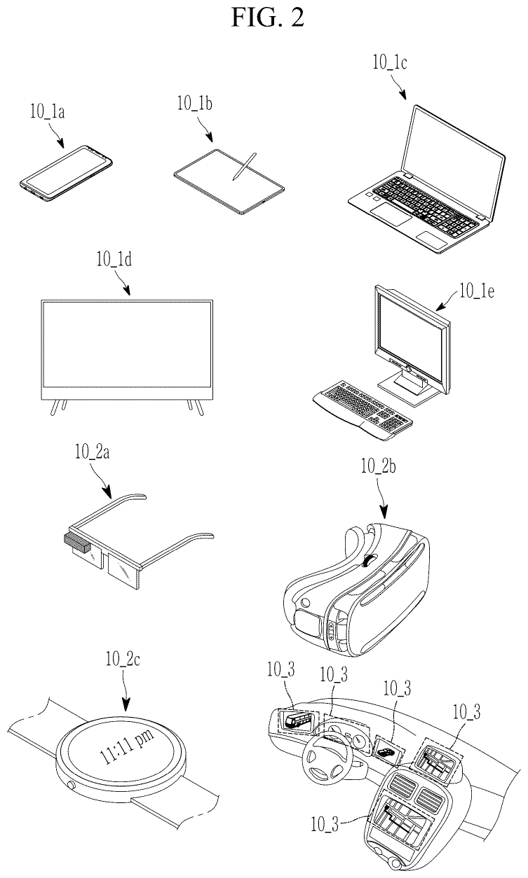

FIG. 2 shows schematic diagrams of electronic devices according to various embodiments.

Referring to FIG. 2, various electronic devices to which display devices according to some embodiments are applied may include not only electronic devices for image display such as a smartphone 10_1a, a tablet PC 10_1b, a laptop 10_1c, a TV 10_1d, and a desktop monitor 10_1e, but also wearable electronic devices including display modules such as smart glasses 10_2a, a head mount display 10_2b, and a smart watch 10_2c, and automotive electronic devices 10_3 including display modules such as automobile instrument panels, center fascias, CID (Center Information Display) located on dashboards, room mirror displays, and the like.

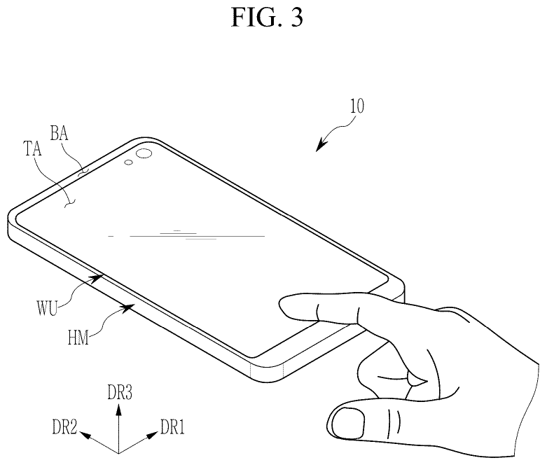

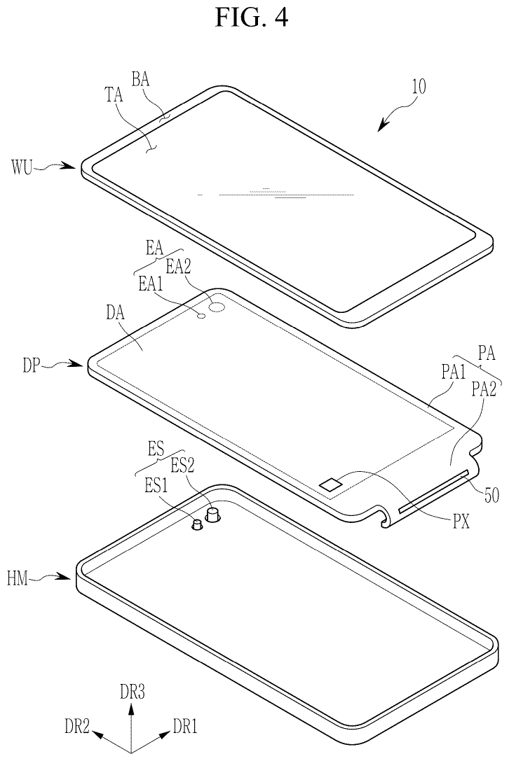

Hereinafter, the structure of a schematic electronic device will be examined through FIGS. 3 to 4. FIG. 3 is a schematic perspective view showing a usage state of an electronic device according to some embodiments, and FIG. 4 is an exploded perspective view of an electronic device according to some embodiments.

Referring to FIG. 3, the electronic device 10 may display an image toward a third direction DR3 on a display surface parallel to each of a first direction DR1 and a second direction DR2. The display surface on which images are displayed may correspond to a front surface of the electronic device 10 and may correspond to a front surface of the cover window WU. The images may include moving images (e.g., video images) as well as still images (e.g., static images).

According to some embodiments, the front surface (or upper surface) and the rear surface (or lower surface) of each member are defined based on the direction in which the image is displayed. The front surface and the rear surface oppose each other in the third direction DR3, and the normal direction of each of the front surface and the rear surface may be parallel to the third direction DR3. The separation distance in the third direction DR3 between the front surface and the rear surface may correspond to the thickness of the display panel in the third direction DR3.

The electronic device 10 according to some embodiments may detect a user's input (refer to the hand in FIG. 3) applied from the outside. The user's input may include various forms of external inputs such as a part of the user's body, light, heat, or pressure. According to some embodiments, the user's input is illustrated as the user's hand applied to the front surface. However, embodiments according to the present disclosure are not limited thereto. The user's input may be provided in various forms, and the electronic device 10 may also detect a user's input applied to a side or rear surface of the electronic device 10 according to the structure of the electronic device 10.

Referring to FIGS. 3 and 4, the electronic device 10 may include a cover window WU, a housing HM, a display panel DP, and an optical element ES. According to some embodiments, the cover window WU and the housing HM may be combined to constitute an appearance of the electronic device 10.

The cover window WU may include an insulating panel. For example, the cover window WU may comprise glass, plastic, or a combination thereof.

The front surface of the cover window WU may define the front surface of the electronic device 10. The transmission area TA may be an optically transparent area. For example, the transmission area TA may be an area having a visible light transmittance of 90% (or about 90%) or more.

The blocking area BA may define the shape of the transmission area TA. The blocking area BA is adjacent to the transmission area TA and may surround the transmission area TA. The blocking area BA may be an area having a relatively low light transmittance compared to the transmission area TA. The blocking area BA may include an opaque material which blocks light. The blocking area BA may have a color. The blocking area BA may be defined by a bezel layer provided separately from a transparent substrate defining the transmission area TA, or may be defined by an ink layer formed by being inserted or colored in the transparent substrate.

The display device may include a display panel DP for displaying images and a driver 50. The display panel DP may include a front surface including a display area DA and a non-display area PA. The display area DA may be an area in which pixels operate according to electrical signals to emit light.

According to some embodiments, the display area DA may be an area in which images are displayed including pixels, and at the same time, may be an area in which external input is detected with a touch sensor positioned above the pixels in the third direction DR3.

The transmission area TA of the cover window WU may at least partially overlap with the display area DA of the display panel DP. For example, the transmission area TA may overlap with the front surface of the display area DA or may overlap with at least a portion of the display area DA. Accordingly, the user may view an image through the transmission area TA or may provide external input based on the image. However, embodiments according to the present disclosure are not limited thereto. For example, an area in which an image is displayed and an area in which external input is detected in the display area DA may be separated from each other.

The non-display area PA of the display panel DP may at least partially overlap with the blocking area BA of the cover window WU. The non-display area PA may be an area covered by the blocking area BA. The non-display area PA is adjacent to the display area DA and may surround the display area DA. No image is displayed in the non-display area PA, and driving circuits or driving wirings for driving the display area DA may be arranged in the non-display area PA. The non-display area PA may include a first peripheral area PA1 positioned outside the display area DA and a second peripheral area PA2 including the driver 50, connection wirings, and a bending area. In the embodiments of FIG. 4, the first peripheral area PA1 is located on three sides of the display area DA, and the second peripheral area PA2 is located on the remaining one side of the display area DA.

According to some embodiments, the display panel DP may be assembled in a flat state in which the display area DA and the non-display area PA face the cover window WU. However, embodiments according to the present disclosure are not limited thereto. A portion of the non-display area PA of the display panel DP may be bent. At this time, a portion of the non-display area PA faces the rear surface of the electronic device 10, so that the blocking area BA shown on the front surface of the electronic device 10 may be relatively reduced, and in FIG. 4, the second peripheral area PA2 may be bent and positioned on the rear surface of the display area DA and then assembled.

In addition, the display panel DP may include a component area EA, specifically a first component area EA1 and a second component area EA2. The first component area EA1 and the second component area EA2 may be at least partially surrounded by the display area DA. The first component area EA1 and the second component area EA2 are shown spaced apart from each other, but are not limited thereto and may be at least partially connected. The first component area EA1 and the second component area EA2 may be areas in which components using infrared rays, visible light, or sound are located below them.

The display area DA includes a plurality of light emitting diodes and a plurality of pixel circuit units which generate and transmit light emitting current to each of the plurality of light emitting diodes. Here, one light emitting diode and one pixel circuit unit are called a pixel PX. In the display area DA, one pixel circuit unit and one light emitting diode are formed in a one-to-one correspondence.

The first component area EA1 may include a transmission part (optical sensor area to be described later) through which light and/or sound may pass and a display part (light emission area to be described later) including a plurality of pixels. The transmission part is positioned between adjacent pixels and comprises a transparent layer through which light and/or sound may pass. The display part may be formed to have one unit structure by combining a plurality of pixels, and a transmission part may be positioned between adjacent unit structures.

The second component area EA2 includes an area comprising a transparent layer so that light may pass through, in which conductive layers or semiconductor layers are not positioned, and may have a structure which does not block light by including openings in pixel defining layers, light blocking layers, or the like that include light blocking materials.

The driver 50 may be mounted on the second peripheral area PA2, may be mounted on a bending part, or may be positioned on one of the two sides of the bending part. The driver 50 may be provided in a chip form.

The driver 50 may be electrically connected to the display area DA to transmit electrical signals to the display area DA. For example, the driver 50 may provide data signals to pixels PX located in the display area DA. Alternatively, the driver 50 may include a touch driving circuit and may be electrically connected to a touch sensor located in the display area DA. The driver 50 may include various circuits in addition to the circuits described above or may be designed to provide various electrical signals to the display area DA.

A pad part may be positioned at an end of the second peripheral area PA2, and may be electrically connected to a Flexible Printed Circuit Board (FPCB) including a driving chip through the pad part. Here, the driving chip positioned on the flexible printed circuit board may include various driving circuits for driving the electronic device 10 or connectors for power supply. According to some embodiments, a rigid printed circuit board (PCB) may be used instead of the flexible printed circuit board.

The optical element ES may be located below the display panel DP. The optical element ES may include a first optical element ES1 overlapping with the first component area EA1 and a second optical element ES2 overlapping with the second component area EA2.

The first optical element ES1 may be an electronic element using light or sound. For example, the first optical element ES1 may be a sensor which receives and uses light such as an infrared sensor, a sensor which outputs and detects light or sound to measure distance or recognize fingerprints, a small lamp which outputs light, or a speaker which outputs sound. In the case of electronic elements using light, it is of course possible to use light of various wavelength bands such as visible light, infrared light, and ultraviolet light.

The second optical element ES2 may be at least one of a camera, an infrared camera (IR camera), a dot projector, an infrared illuminator (IR illuminator), or a time-of-flight sensor (ToF sensor).

The housing HM may be combined with the cover window WU. The cover window WU may be located on the front surface of the housing HM. The housing HM may be combined with the cover window WU to provide an accommodation space. The display panel DP and the optical element ES may be accommodated in an accommodation space provided between the housing HM and the cover window WU.

The housing HM may include a material having relatively high rigidity. For example, the housing HM may include glass, plastic, or metal, or may include a plurality of frames and/or plates composed of a combination thereof. The housing HM may stably protect the components of the electronic device 10 accommodated in the internal space from external impacts.

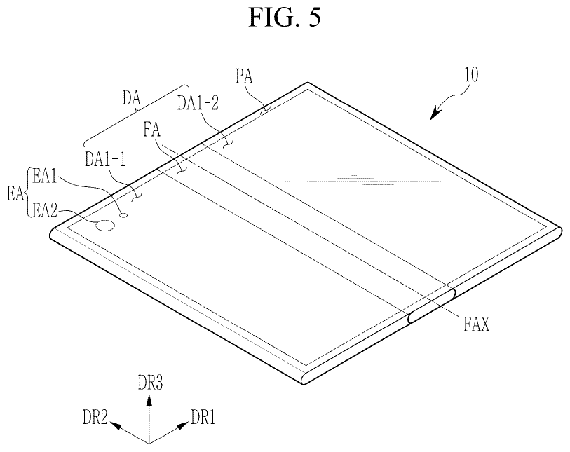

Hereinafter, an electronic device according to some embodiments will be examined through FIG. 5. FIG. 5 is a perspective view schematically showing an electronic device according to some embodiments. Some description of the same components as the aforementioned components may be omitted.

The embodiments of FIG. 5 shows a foldable display device having a structure in which the electronic device 10 is folded through a folding axis FAX.

According to some embodiments, the electronic device 10 may be a foldable display device. The electronic device 10 may be folded outward or inward with reference to the folding axis FAX. In case that the electronic device 10 is folded outward with reference to the folding axis FAX, the display surfaces of the electronic device 10 are positioned outward in the third direction DR3, respectively, so that images may be displayed in both directions. In case that the electronic device 10 is folded inward with reference to the folding axis FAX, the display surface may not be visible from the outside.

According to some embodiments, the electronic device 10 may include a display area DA, a component area EA, and a non-display area PA. The display area DA may be divided into a 1-1 display area DA1-1, a 1-2 display area DA1-2, and a folding area FA. The 1-1 display area DA1-1 and the 1-2 display area DA1-2 may be positioned on the left and right sides, respectively, with reference to (or centered on) the folding axis FAX, and a folding area FA may be positioned between the 1-1 display area DA1-1 and the 1-2 display area DA1-2. At this time, in case that the electronic device 10 is folded outward with reference to the folding axis FAX, the 1-1 display area DA1-1 and the 1-2 display area DA1-2 are positioned on both sides in the third direction DR3 and may display images in both directions. In addition, in case that the electronic device 10 is folded inward with reference to the folding axis FAX, the 1-1 display area DA1-1 and the 1-2 display area DA1-2 may not be visible from the outside.

Although this specification has described a folding axis parallel to the second direction DR2, it is not limited thereto, and an electronic device 10 which folds with reference to a folding axis parallel to the first direction DR1 may also be possible.

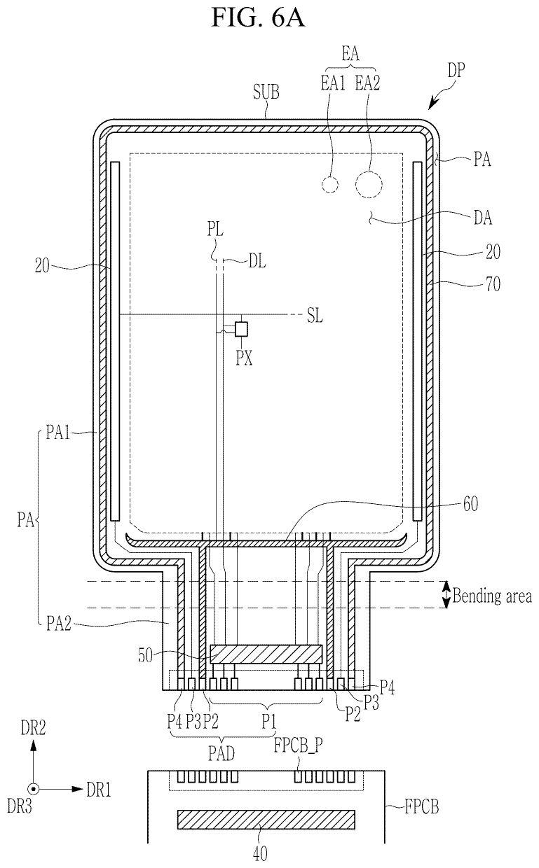

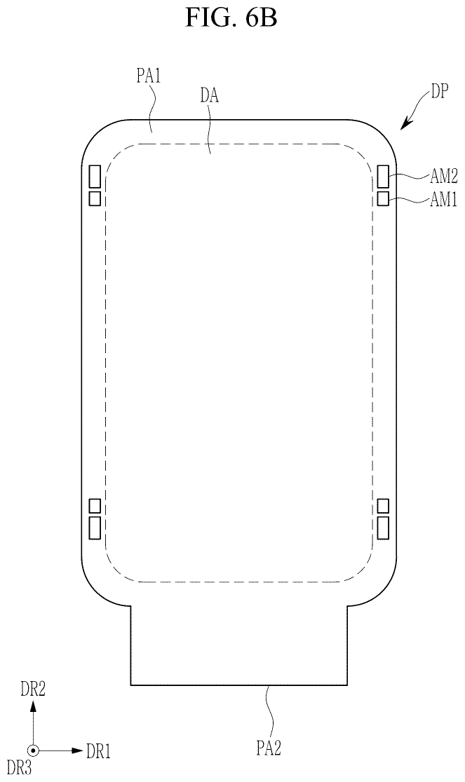

Hereinafter, the structure of a display panel will be examined with reference to FIGS. 6A and 6B. FIG. 6A is a plan view of a display panel according to some embodiments, and FIG. 6B is a plan view showing conductive pattern positions in a display panel according to some embodiments.

First, referring to FIG. 6A, the display panel DP may include a display area DA, a component area EA, and a non-display area PA, and the non-display area PA may be defined along the edge of the display area DA. The non-display area PA may include a first non-display area PA1 positioned outside the display area DA and a second non-display area PA2 including a data driver 50, connection wirings, a bending area, and the like.

The display panel DP includes a plurality of pixels PX. The plurality of pixels PX may be located in the display area DA. Each pixel PX includes a light emitting element and a pixel circuit unit connected to the light emitting element. Each pixel PX emits, for example, red, green, blue, or white light, and may include, for example, an organic light emitting diode.

The display panel DP may include a plurality of signal lines and a pad part. The plurality of signal lines may include scan lines SL extending in the first direction DR1, data lines DL extending in the second direction DR2, and driving voltage lines PL.

The scan driver 20 is positioned on the left and right sides of the display area DA and generates and transmits scan signals to each pixel PX through the scan lines SL. The pixel PX may receive scan signals together from two scan drivers 20 positioned on the left and right sides.

The pad part PAD (hereinafter also referred to as a circuit board pad part) is located at an end of the second non-display area PA2 of the display panel DP and may include a plurality of terminals P1, P2, P3, and P4. The pad part PAD may be exposed without being covered by an insulating layer and electrically connected to a flexible printed circuit board (FPCB). The pad part PAD may be electrically connected to a pad part FPCB_P of the flexible printed circuit board FPCB. The flexible printed circuit board FPCB may transmit signals or power from the IC driving chip 40 to the pad part PAD.

The IC driving chip 40 changes a plurality of video signals transmitted from the outside into a plurality of video data signals and transmits the changed signals to the data driver 50 through the terminal P1. In addition, the IC driving chip 40 receives vertical synchronization signals, horizontal synchronization signals, and clock signals to generate control signals for controlling the driving of the scan driver 20 and the data driver 50 and transmit them to each through the terminals P3 and P1. The IC driving chip 40 transmits a driving voltage ELVDD to the driving voltage supply wiring 60 through the terminal P2. In addition, the IC driving chip 40 may transmit a common voltage ELVSS to each of the common voltage transmission wirings 70 through the terminal P4.

The data driver 50 is located on the second non-display area PA2, generates data voltages to be applied to each pixel PX, and transmits them to each data line DL. The data driver 50 may be located on a side of the display panel DP, for example, between the pad part PAD and the display area DA.

Data lines DL connected to pixels PX other than pixels PX positioned above and below the component area EA along the second direction DR2 extend along the second direction DR2 and may have a linear structure. In contrast, data lines DL connected to pixels PX positioned above and below the component area EA extend along the second direction DR2, but may include portions extending along the periphery of the component area EA around the component area EA.

The driving voltage supply wiring 60 is located on the second non-display area PA2. For example, the driving voltage supply wiring 60 may be located between the data driver 50 and the display area DA. The driving voltage supply wiring 60 provides a driving voltage ELVDD to the pixels PX. The driving voltage supply wiring 60 is arranged in the first direction DR1 and may be connected to a plurality of driving voltage lines PL arranged in the second direction DR2.

The common voltage transmission wiring 70 is located on the second non-display area PA2. The common voltage transmission wiring 70 may have a form surrounding the substrate SUB. The common voltage transmission wiring 70 transmits a common voltage ELVSS to an electrode (for example, a cathode) of a light emitting element included in the pixel PX.

The second non-display area PA2 may include a bending area. The bending area may be positioned between the display area DA and the pad part PAD. A plurality of inorganic layers may be removed from the bending area. The bending area does not include inorganic layers. An insulating layer comprising organic material may be positioned in the bending area. In the bending area, an insulating layer comprising organic material may be positioned at the outermost part.

Next, referring to FIG. 6B, a display panel DP according to some embodiments may include a plurality of opening patterns AM1 and AM2. The opening patterns AM1 and AM2 may indicate positions of components necessary in a manufacturing process of an electronic device. For example, the opening patterns AM1 and AM2 may be used to align the display panel and the cover window in a process of combining the display panel and the cover window.

Although FIG. 6B shows a total of eight opening patterns AM1 and AM2, the opening patterns AM1 and AM2 may be variously displayed on the substrate SUB in a range necessary for alignment.

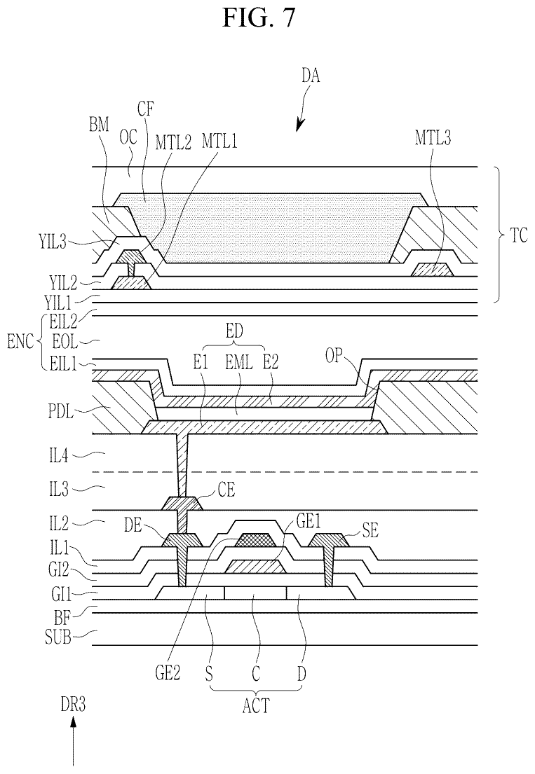

Hereinafter, a stacked structure of a pixel positioned in a display area according to some embodiments will be examined with reference to FIG. 7. FIG. 7 is a cross-sectional view of a display panel corresponding to a display area. Some description of the same components as the aforementioned components may be omitted.

Referring to FIG. 7, the substrate SUB may include a material having rigid characteristics such as glass or a flexible material which may be bent such as plastic or polyimide.

A buffer layer BF may be positioned on the substrate SUB. The buffer layer BF may flatten the surface of the substrate SUB and block penetration of impurity elements. The buffer layer BF may include an inorganic material, and for example, may include inorganic insulating materials such as silicon nitride (SiNx), silicon oxide (SiOx), and silicon oxynitride (SiOxNy).

A semiconductor layer ACT may be positioned on the buffer layer BF. The semiconductor layer ACT of the display device according to some embodiments may include amorphous silicon, polycrystalline silicon, or an oxide semiconductor.

The semiconductor layer ACT may include a channel region C, a source region S, and a drain region D which are distinguished according to whether impurities are doped. The source region S and the drain region D may be doped with impurities to have conductive characteristics corresponding to a conductor.

A first gate insulating layer GI1 may be positioned on the semiconductor layer ACT. The first gate insulating layer GI1 may cover the semiconductor layer ACT and the substrate SUB. The first gate insulating layer GI1 may include inorganic insulating materials such as silicon nitride (SiNx), silicon oxide (SiOx), and silicon oxynitride (SiOxNy). The first gate insulating layer GI1 may be a single layer or a multi-layer structure including the above inorganic insulating materials.

A gate electrode GE1 may be positioned on the first gate insulating layer GI1. The gate electrode GE1 may include metals or metal alloys such as copper (Cu), molybdenum (Mo), aluminum (AI), silver (Ag), chromium (Cr), tantalum (Ta), and titanium (Ti). The gate electrode GE1 may be a single layer or multiple layers. A region of the semiconductor layer ACT which overlaps with the gate electrode GE1 in a plan view may be the channel region C.

A second gate insulating layer GI2 may be positioned on the gate electrode GE1. The second gate insulating layer GI2 may include inorganic insulating materials such as silicon nitride (SiNx), silicon oxide (SiOx), and silicon oxynitride (SiOxNy). The second gate insulating layer GI2 may be a single layer or a multi-layer structure including the above inorganic insulating materials.

A capacitor electrode GE2 may be positioned on the second gate insulating layer GI2. The capacitor electrode GE2 may overlap with the gate electrode GE1 to form a capacitor.

A first insulating layer IL1 may be positioned on the capacitor electrode GE2. The first insulating layer IL1 may include inorganic insulating materials such as silicon nitride (SiNx), silicon oxide (SiOx), and silicon oxynitride (SiOxNy). The first insulating layer IL1 may be a single layer or a multi-layer structure including the above inorganic insulating materials.

A source electrode SE and a drain electrode DE may be positioned on the first insulating layer IL1. The source electrode SE and the drain electrode DE are electrically connected to the source region S and the drain region D of the semiconductor layer ACT, respectively, through openings defined in the first insulating layer IL1, the second gate insulating layer GI2, and the first gate insulating layer GI1.

Accordingly, the semiconductor layer ACT, gate electrode GE1, source electrode SE, and drain electrode DE constitute one transistor. According to some embodiments, the transistor may include only the source region and the drain region of the semiconductor layer ACT instead of the source electrode SE and the drain electrode DE.

The source electrode SE and the drain electrode DE may include metals or metal alloys such as aluminum (AI), copper (Cu), silver (Ag), gold (Au), platinum (Pt), palladium (Pd), nickel (Ni), molybdenum (Mo), tungsten (W), titanium (Ti), chromium (Cr), and tantalum (Ta). The source electrode SE and the drain electrode DE may be a single layer or multiple layers. The source electrode SE and the drain electrode DE according to some embodiments may be a triple layer including an upper layer, a middle layer, and a lower layer, wherein the upper layer and the lower layer may include titanium (Ti), and the middle layer may include aluminum (Al).

A second insulating layer IL2 may be positioned on the source electrode SE and the drain electrode DE. The second insulating layer IL2 covers the source electrode SE and the drain electrode DE. The second insulating layer IL2 may planarize the surface of the substrate SUB on which the transistor is provided. The second insulating layer IL2 may be an organic insulating layer and may include one or more materials selected from the group comprising polyimide, polyamide, acrylic resin, benzocyclobutene, and phenol resin. The second insulating layer IL2 may be a single layer or multiple layers according to some embodiments. The second insulating layer IL2 may include at least two insulating layers.

A connection electrode CE may be positioned on the second insulating layer IL2. The connection electrode CE may include the same material as the source electrode SE. The connection electrode CE may electrically connect the first electrode E1 and the drain electrode DE. According to some embodiments, the connection electrode CE may be omitted.

A third insulating layer IL3 and a fourth insulating layer IL4 may be positioned on the connection electrode CE. The third insulating layer IL3 and the fourth insulating layer IL4 may include organic materials. The third insulating layer IL3 and the fourth insulating layer IL4 may include the same organic material or may include different organic materials. In case that the third insulating layer IL3 and the fourth insulating layer IL4 include the same organic material, substantial layer distinction may be difficult.

A first electrode E1 may be positioned on the fourth insulating layer IL4. The first electrode E1 is also called an anode electrode and may be a single layer including a transparent conductive oxide layer or a metal material, or multiple layers including them. The transparent conductive oxide layer may include Indium Tin Oxide (ITO), poly-ITO, Indium Zinc Oxide (IZO), Indium Gallium Zinc Oxide (IGZO), and Indium Tin Zinc Oxide (ITZO). The metal material may include silver (Ag), molybdenum (Mo), copper (Cu), gold (Au), and aluminum (AI). For example, the first electrode E1 may have a three-layer structure of ITO/Ag/ITO.

The first electrode E1 may be electrically connected to the drain electrode DE. The first electrode E1 may receive an output current to be transmitted from the drain electrode DE to the light emitting layer EML.

A pixel defining layer PDL may be positioned on the first electrode E1 and the fourth insulating layer IL4. The pixel defining layer PDL may overlap with the edge of the first electrode E1 and may be spaced apart from the center of the first electrode E1. The pixel defining layer PDL may partition the formation position of the light emitting layer EML so that the light emitting layer EML may be positioned on the portion in which the upper surface of the first electrode E1 is exposed.

The pixel defining layer PDL may be an organic insulating layer including one or more materials selected from the group comprising polyimide, polyamide, acrylic resin, benzocyclobutene, and phenol resin, and according to some embodiments, the pixel defining layer PDL may be formed as a Black Pixel Define Layer (BPDL) including black pigment.

The light emitting layer EML may be positioned in a pixel opening OP of the pixel defining layer PDL. The light emitting layer EML may include organic materials which emit red, green, blue, or other colors of light. The light emitting layer EML which emits red, green, and blue light may include low molecular weight or high molecular weight organic materials. Although FIG. 7 shows the light emitting layer EML as a single layer, in reality, auxiliary layers such as an electron injection layer, an electron transport layer, a hole transport layer, and a hole injection layer may also be included above and below the light emitting layer EML, with a hole injection layer and a hole transport layer positioned below the light emitting layer EML, and an electron transport layer and an electron injection layer positioned above the light emitting layer EML.

The second electrode E2 may be positioned on the pixel defining layer PDL and the light emitting layer EML. The second electrode E2 is also called a cathode electrode and may be formed as a transparent conductive layer including Indium Tin Oxide (ITO), Indium Zinc Oxide (IZO), Indium Gallium Zinc Oxide (IGZO), and Indium Tin Zinc Oxide (ITZO). In addition, the second electrode E2 may have semi-transparent characteristics, and in this case, may constitute a micro-cavity together with the first electrode E1. According to the micro-cavity structure, light of a specific wavelength is emitted upward due to the spacing and characteristics between the two electrodes, and as a result, red, green, or blue may be displayed.

The first electrode E1, the light emitting layer EML, and the second electrode E2 may constitute one light emitting device ED.

An encapsulation layer ENC is positioned on the second electrode E2. The encapsulation layer ENC may include at least one inorganic layer and at least one organic layer, and according to some embodiments, may have a triple layer structure including a first inorganic encapsulation layer EIL1, an organic encapsulation layer EOL, and a second inorganic encapsulation layer EIL2.

The encapsulation layer ENC may protect the light emitting layer EML comprising organic materials from moisture or oxygen which may be introduced from the outside. According to some embodiments, the encapsulation layer ENC may include a structure in which inorganic layers and organic layers are further sequentially stacked.

A touch sensing unit TC may be positioned on the encapsulation layer ENC.

The touch sensing unit TC according to some embodiments may include a plurality of sensing insulating layers YIL1, YIL2, and YIL3 and sensing electrodes MTL1, MTL2, and MTL3.

A lower sensing insulating layer YIL1 may be positioned on the encapsulation layer ENC. The lower sensing insulating layer YIL1 may be an inorganic insulating layer. The inorganic material included in the inorganic insulating layer may be at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. According to some embodiments, the lower sensing insulating layer YIL1 may be omitted.

A sensing electrode connection portion MTL1, a first sensing insulating layer YIL2, and a plurality of sensing electrodes MTL2 and MTL3 may be positioned on the lower sensing insulating layer YIL1. The plurality of sensing electrodes MTL2 and MTL3 may be positioned on the same layer, and the sensing electrode connection portion MTL1 may be positioned on a different layer from the plurality of sensing electrodes MTL2 and MTL3.

The sensing electrode connection portion MTL1, the first sensing insulating layer YIL2, and the plurality of sensing electrodes MTL2 and MTL3 may constitute a sensing sensor. The sensing sensor may be classified into methods such as resistive type, capacitive type, electro-magnetic type, and optical type. The sensing sensor according to some embodiments may use a capacitive type sensor.

The first sensing insulating layer YIL2 may be positioned between the sensing electrode connection portion MTL1 and the plurality of sensing electrodes MTL2 and MTL3. The first sensing insulating layer YIL2 may include an inorganic insulating material. The inorganic insulating material may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

A plurality of sensing electrodes MTL2 and MTL3 may be positioned on the first sensing insulating layer YIL2. The plurality of sensing electrodes MTL2 and MTL3 may include a plurality of first sensing electrodes MTL3 and a plurality of second sensing electrodes MTL2. The first sensing electrode MTL3 and the second sensing electrode MTL2 may be electrically insulated. The first sensing insulating layer YIL2 may include an opening which exposes the upper surface of the sensing electrode connection portion MTL1. Through the opening of the first sensing insulating layer YIL2, the sensing electrode connection portion MTL1 may be connected to the second sensing electrode MTL2 to electrically connect two adjacent second sensing electrodes MTL2. A sensing electrode connection portion connecting the first sensing electrode MTL3 may be formed on the same layer as the first sensing electrode MTL3 and the second sensing electrode MTL2.

The plurality of sensing electrodes MTL2 and MTL3 may include conductive materials with good conductivity. For example, the plurality of sensing electrodes MTL2 and MTL3 may include metals or metal alloys such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). The plurality of sensing electrodes MTL2 and MTL3 may be a single layer or multiple layers. At this time, the plurality of sensing electrodes MTL2 and MTL3 may include openings so that light emitted from the light emitting diode may be emitted upward without interference. According to some embodiments, the plurality of sensing electrodes MTL2 and MTL3 may be a triple layer including an upper layer, a middle layer, and a lower layer, wherein the upper layer and the lower layer may include titanium (Ti), and the middle layer may include aluminum (Al).

A second sensing insulating layer YIL3 may be positioned on the plurality of sensing electrodes MTL2 and MTL3. The second sensing insulating layer YIL3 may include an organic insulating material or an inorganic insulating material. The organic insulating material may include, for example, at least one of acetate-based compounds, acrylic resin, polyimide resin, polyamide resin, or Alq₃ [Tris(8-hydroxyquinolinato)aluminium].

The second sensing insulating layer YIL3 may cover the plurality of sensing electrodes MTL2 and MTL3 and the first sensing insulating layer YIL2. The second sensing insulating layer YIL3 may mostly overlap with the entire surface of the substrate SUB.

A color filter CF and a light blocking layer BM may be positioned on the second sensing insulating layer YIL3.

The color filter CF includes a red color filter which transmits red light, a green color filter which transmits green light, and a blue color filter which transmits blue light. Each color filter CF may be positioned to overlap with the first electrode E1 of the light emitting diode. Because light emitted from the light emitting layer EML may be emitted while being changed to a corresponding color as it passes through the color filter, all light emitted from the light emitting layer EML may have the same color. However, the light emitting layer EML may emit light of different colors, and by passing through color filters of the same color, the displayed color sense may be enhanced.

A light blocking layer BM may be positioned between adjacent color filters CF. The light blocking layer BM may overlap with the pixel defining layer PDL. The light blocking layer BM may include a light blocking material which absorbs or blocks light.

However, this is not limited thereto, and at least two color filters may overlap in a non-light emitting area corresponding to between adjacent pixels. For example, a blue color filter and a red color filter may overlap, or a blue color filter, a green color filter, and a red color filter may overlap to replace the light blocking layer.

An overcoat layer OC may be positioned on the color filter CF and the light blocking layer BM. The overcoat layer OC may planarize the upper surface of the touch sensing unit TC. The overcoat layer OC may be a transparent organic insulating layer including one or more materials selected from the group comprising polyimide, polyamide, acrylic resin, benzocyclobutene, phenol resin, and acetate-based compounds.

The thickness of the overcoat layer OC may be in a range of 1.0 (or about 1.0) micrometer to 2.0 (or about 2.0) micrometers, for example, 1.2 (or about 1.2) micrometers to 1.8 (or about 1.8) micrometers, and for example, 1.5 (or about 1.5) micrometers. In case that the thickness of the overcoat layer OC satisfies the numerical range as described above, it may be effective in reducing step differences in the non-display area to be described later. According to some embodiments, the thickness of the overcoat layer OC may be greater than the thickness of the light blocking layer BM and the color filter CF.

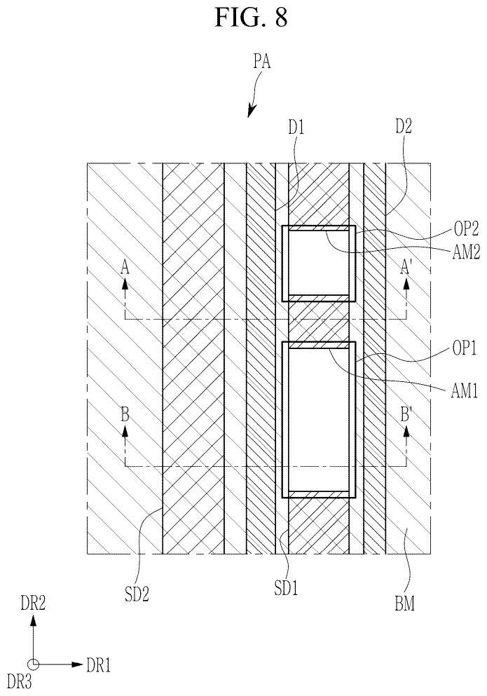

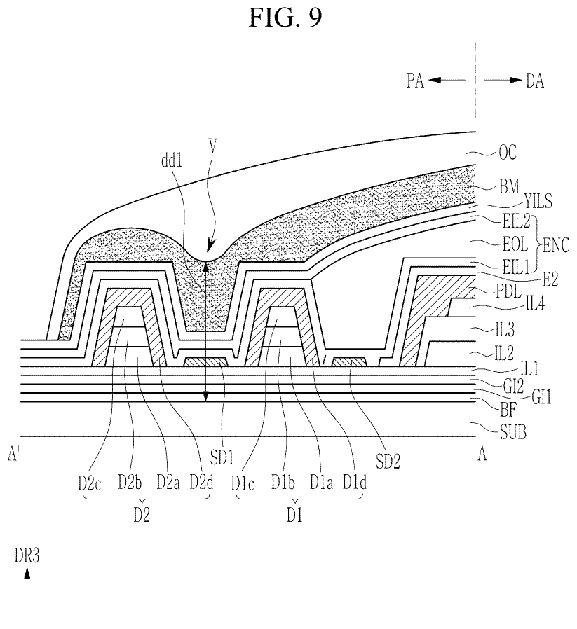

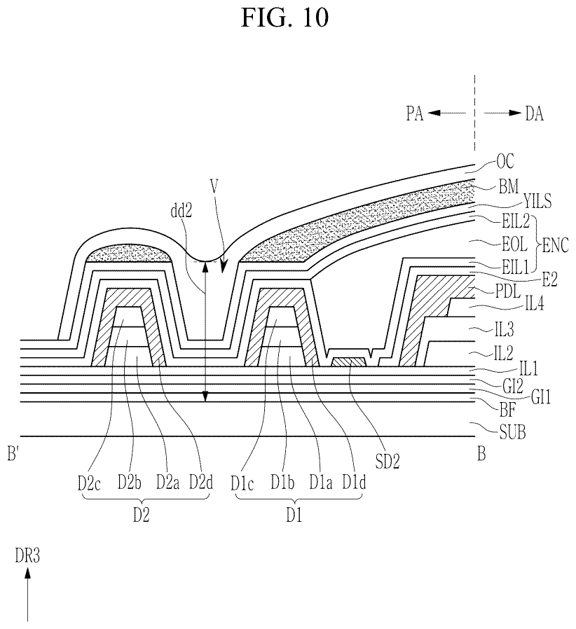

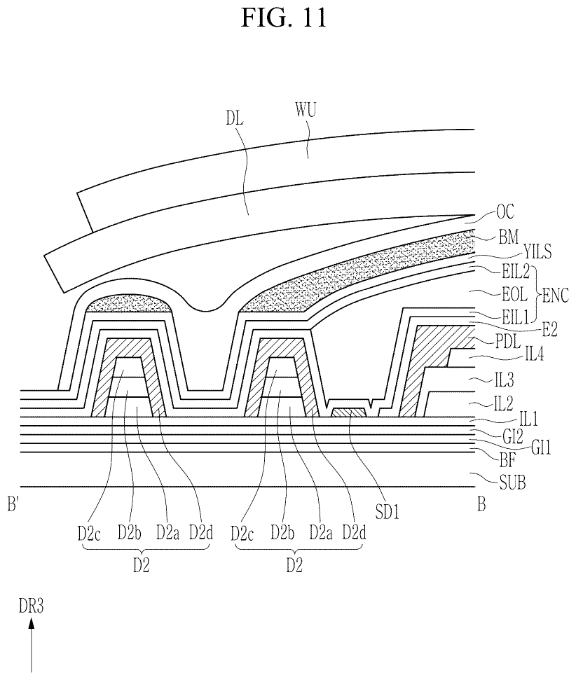

Hereinafter, the non-display area of a display device according to some embodiments will be examined with reference to FIGS. 8 to 11. FIG. 8 is a plan view of a partial area in which opening patterns are positioned in the non-display area, FIG. 9 is a cross-sectional view taken along the line A-A′ of FIG. 8, FIG. 10 is a cross-sectional view taken along the line B-B′ of FIG. 8, and FIG. 11 is a cross-sectional view showing a portion of the non-display area. Some description of the same components as the aforementioned components may be omitted.

First, referring to FIGS. 8 and 9, a substrate SUB, a buffer layer BF, a first gate insulating layer GI1, a second gate insulating layer GI2, a first insulating layer IL1, a second insulating layer IL2, a third insulating layer IL3, a fourth insulating layer IL4, a pixel defining layer PDL, a second electrode E2, an encapsulation layer ENC, a plurality of touch insulating layers ILS, a light blocking layer BM, and an overcoat layer OC extending from the display area DA may be positioned in the non-display area PA. The plurality of touch insulating layers ILS may include a lower touch insulating layer YIL1, a first touch insulating layer YIL2, and a second touch insulating layer YIL3.

A first dam D1 and a second dam D2 may be positioned in the non-display area PA. The first dam D1 may be positioned adjacent to the display area compared to the second dam D2. The first dam D1 may prevent or reduce the organic encapsulation layer EOL overflowing into the non-display area PA. An end of the organic encapsulation layer EOL may be located adjacent to the first dam D1.

The first dam D1 may include a 1-1 layer D1a, a 1-2 layer D1b, a 1-3 layer D1c, and a 1-4 layer D1d. The 1-1 layer D1a includes the same material as the second insulating layer IL2 of the display area DA and may be manufactured in the same process. The 1-2 layer D1b includes the same material as the third insulating layer IL3 of the display area DA and may be manufactured in the same process. The 1-3 layer D1c includes the same material as the fourth insulating layer IL4 of the display area DA and may be manufactured in the same process. The 1-4 layer D1d includes the same material as the pixel defining layer PDL of the display area DA and may be manufactured in the same process. In this specification, the 1-1 layer Dia, the 1-2 layer D1b, and the 1-3 layer D1c are shown with edges aligned in cross-section, and the 1-4 layer D1d is shown covering the sides of the 1-1 layer D1a, the 1-2 layer D1b, and the 1-3 layer D1c, but it is not limited to this shape. In addition, at least one of the 1-1 layer D1a, the 1-2 layer D1b, the 1-3 layer D1c, or the 1-4 layer D1d may be omitted.

The second dam D2 may include a 2-1 layer D2a, a 2-2 layer D2b, a 2-3 layer D2c, and a 2-4 layer D2d. The 2-1 layer D2a includes the same material as the second insulating layer IL2 of the display area DA and may be manufactured in the same process. The 2-2 layer D2b includes the same material as the third insulating layer IL3 of the display area DA and may be manufactured in the same process. The 2-3 layer D2c includes the same material as the fourth insulating layer IL4 of the display area DA and may be manufactured in the same process. The 2-4 layer D2d includes the same material as the pixel defining layer PDL of the display area DA and may be manufactured in the same process. In this specification, the 2-1 layer D2a, the 2-2 layer D2b, and the 2-3 layer D2c are shown with edges aligned in cross-section, and the 2-4 layer D2d is shown covering the sides of the 2-1 layer D2a, the 2-2 layer D2b, and the 2-3 layer D2c, but it is not limited to this shape. At least one of the 2-1 layer D2a, the 2-2 layer D2b, the 2-3 layer D2c, or the 2-4 layer D2d may be omitted.

This specification shows embodiments in which the first dam D1 and the second dam D2 equally include four layers, but it is not limited thereto, and the first dam D1 and the second dam D2 may have different shapes. For example, the second dam D2 may include four layers, and the first dam D1 may be modified to include three layers.

Referring to FIG. 8, conductive patterns SD1 and SD2 may be positioned between the display area and the first dam D1, and between the first dam D1 and the second dam D2. The conductive patterns SD1 and SD2 may include a first conductive pattern SD1 and a second conductive pattern SD2. The conductive patterns SD1 and SD2 may include the same material as the source electrode SE described above in FIG. 7 and may be manufactured in the same process. Alternatively, the conductive patterns SD1 and SD2 may include the same material as the connection electrode CE described above in FIG. 7 and may be manufactured in the same process.

The conductive patterns SD1 and SD2 may include a first conductive pattern SD1 positioned between the first dam D1 and the second dam D2, and a second conductive pattern SD2 positioned between the first dam D1 and the display area DA. According to some embodiments, the second conductive pattern SD2 may be omitted.

Each of the first conductive pattern SD1 and the second conductive pattern SD2 may have a form extending along the second direction DR2.

The first conductive pattern SD1 is positioned between the first dam D1 and the second dam D2 and may include opening patterns AM1 and AM2. This specification shows embodiments in which the first conductive pattern SD1 includes two opening patterns AM1 and AM2, but it is not limited to this number and form.

The first conductive pattern SD1 may include a first opening pattern AM1 and a second opening pattern AM2. Each of the first opening pattern AM1 and the second opening pattern AM2 may have a rectangular shape in plan view, but it is not limited thereto. The first opening pattern AM1 and the second opening pattern AM2 may be spaced apart from each other. The first opening pattern AM1 and the second opening pattern AM2 may have a form spaced apart from each other along the second direction DR2.

The first dam D1 and the second dam D2 may be spaced apart from the first conductive pattern SD1 and the second conductive pattern SD2. The first dam D1 and the second dam D2 may not overlap with the first conductive pattern SD1 and the second conductive pattern SD2. The first dam D1 and the second dam D2 may be spaced apart from the first opening pattern AM1 and the second opening pattern AM2. The first dam D1 and the second dam D2 may not overlap with the first opening pattern AM1 and the second opening pattern AM2. The first opening pattern AM1 and the second opening pattern AM2 may be positioned between the first dam D1 and the second dam D2.

A light blocking layer BM may be positioned on the first dam D1 and the second dam D2. The light blocking layer BM may extend from the display area DA and be positioned in the non-display area PA. The light blocking layer BM may include a first light blocking opening OP1 and a second light blocking opening OP2.

The first light blocking opening OP1 may be positioned between the first dam D1 and the second dam D2. The first light blocking opening OP1 may overlap with the first opening pattern AM1 of the first conductive pattern SD1. The first light blocking opening OP1 may completely overlap with the first opening pattern AM1. An edge of the first light blocking opening OP1 may surround an edge of the first opening pattern AM1. A center of the first light blocking opening OP1 and a center of the first opening pattern AM1 may coincide. However, it is not limited thereto, and the alignment of the first light blocking opening OP1 and the first opening pattern AM1 may be partially misaligned according to manufacturing process errors. The first light blocking opening OP1 may overlap with at least a portion of the first conductive pattern SD1.

The distance between an edge of the first light blocking opening OP1 and an edge of the first opening pattern AM1 may be 10 (or about 10) micrometers or less. The light blocking layer BM may be provided in a form which substantially opens only the opening patterns AM1 and AM2.

The second light blocking opening OP2 may be positioned between the first dam D1 and the second dam D2. The second light blocking opening OP2 may overlap with the second opening pattern AM2 of the first conductive pattern SD1. The second light blocking opening OP2 may completely overlap with the second opening pattern AM2. An edge of the second light blocking opening OP2 may surround an edge of the second opening pattern AM2. A center of the second light blocking opening OP2 and a center of the second opening pattern AM2 may coincide. However, it is not limited thereto, and the alignment of the second light blocking opening OP2 and the second opening pattern AM2 may be partially misaligned according to manufacturing process errors. The second light blocking opening OP2 may overlap with at least a portion of the first conductive pattern SD1.

FIG. 9 is a cross-sectional view of a non-display area without light blocking openings and opening patterns. As shown in FIG. 9, an encapsulation layer ENC may be positioned on the first dam D1, the second dam D2, and the conductive patterns SD1 and SD2. The first inorganic encapsulation layer EIL1 of the encapsulation layer ENC may cover the first dam D1, the second dam D2, and the conductive patterns SD1 and SD2. In cross-section, the first conductive pattern SD1 does not overlap with the organic encapsulation layer EOL, and the second conductive pattern SD2 may overlap with at least a portion of the organic encapsulation layer EOL.

A touch insulating layer YILS may be positioned on the encapsulation layer ENC. In addition, a light blocking layer BM and an overcoat layer OC may be sequentially positioned on the touch insulating layer YILS. The light blocking layer BM and the overcoat layer OC may cover and overlap the first dam D1 and the second dam D2. The light blocking layer BM may fill a valley V between the first dam D1 and the second dam D2. An upper surface of the light blocking layer BM may be curved, but may be provided in a form which fills the valley V. The overcoat layer OC may cover the upper surface of the light blocking layer BM. The overcoat layer OC may provide a generally flat upper surface.

Next, referring to FIGS. 8 and 10, a light blocking layer is not located in an area in which the first light blocking opening OP1 and the first opening pattern AM1 are positioned. Therefore, the valley V between the first dam D1 and the second dam D2 may be filled by the overcoat layer OC.

A first distance dd1 refers to the distance from the upper surface of the substrate SUB to the upper surface of the overcoat layer OC in the valley V of FIG. 9. A second distance dd2 refers to the distance from the upper surface of the substrate SUB to the upper surface of the overcoat layer OC in the valley V of FIG. 10. The difference between the first distance dd1 and the second distance dd2 (dd1−dd2) may be 1.8 (or about 1.8) micrometers or less.

An area in which the opening patterns AM1 and AM2 are not positioned in the valley V is intended to be covered with the light blocking layer BM. In addition, the valley V is intended to be filled by increasing the thickness of the overcoat layer OC. Through this, a step difference between an area in which the opening patterns AM1 and AM2 are positioned (shown in FIG. 10) and an area in which they are not positioned (shown in FIG. 9) may be relatively reduced.

Referring to FIG. 11, a protective layer DL and a cover window WU may be located on the overcoat layer OC. Referring to FIGS. 9 and 10, because the step difference between an area in which the first conductive pattern SD1 is positioned and an area in which it is not positioned in the valley V is relatively reduced, the protective layer DL and the cover window WU located on the overcoat layer OC may be stably combined.

In case that the light blocking layer BM is not located in the valley V or the thickness of the overcoat layer OC is thin, the step difference between areas in the valley V may increase. The overcoat layer OC may have an uneven upper surface. In case that the protective layer DL is located on such an overcoat layer OC, bubbles may remain between the protective layer DL and the overcoat layer OC, and accordingly, the reliability and display quality of the display device may be degraded.

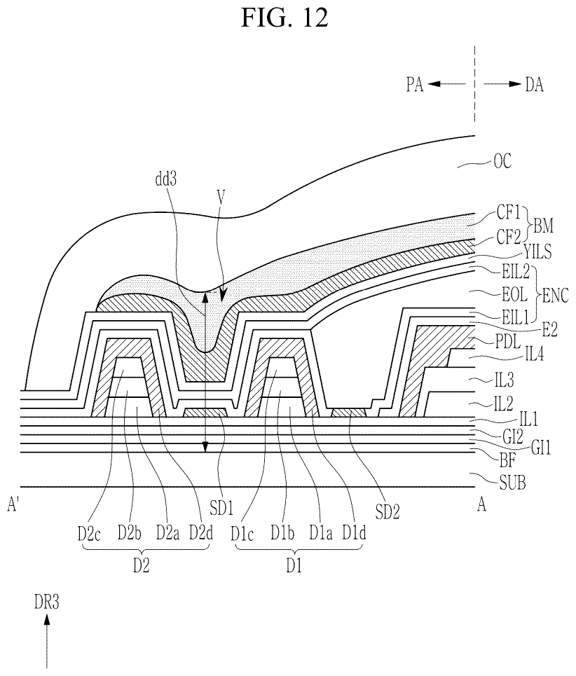

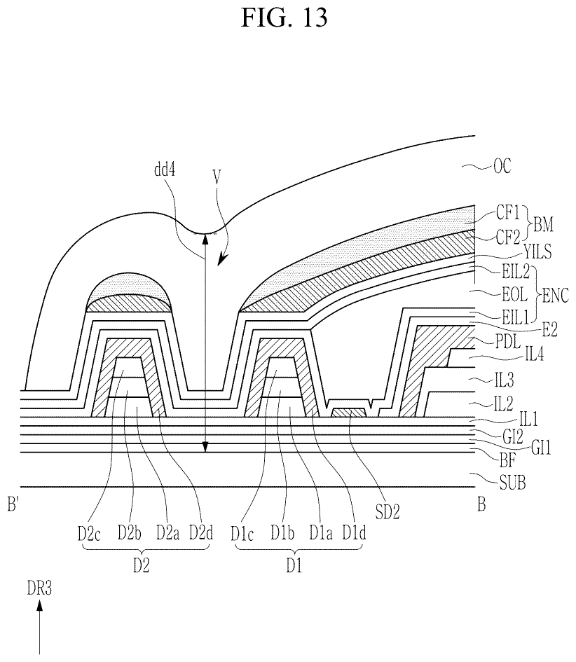

Hereinafter, a display device according to some embodiments will be examined with reference to FIGS. 12 to 13. FIGS. 12 and 13 are cross-sectional views of a non-display area, respectively. Some description of the same components as the aforementioned components may be omitted.

Referring to FIG. 12, the light blocking layer BM according to some embodiments may be a layer in which at least two color filters CF1 and CF2 overlap. In a display device according to some embodiments, a plurality of color filters CF1 and CF2 may be positioned on a touch insulating layer YILS.

Two or more color filters CF1 and CF2 may overlap each other to perform a light blocking function. The first color filter CF1 according to some embodiments may be a red color filter, and the second color filter CF2 may be a blue color filter. The red color filter CF1 may cover the blue color filter CF2. However, it is not limited thereto, and red, green, and blue color filters may overlap in the light blocking area.

According to some embodiments, the first color filter CF1 and the second color filter CF2 may overlap with the first dam D1 and the second dam D2 in the non-display area PA. The first color filter CF1 and the second color filter CF2 may fill a valley V positioned between the first dam D1 and the second dam D2.

An overcoat layer OC may be positioned on the first color filter CF1 and the second color filter CF2. The thickness of the overcoat layer OC may be 3.0 (or about 3.0) micrometers to 4.0 (or about 4.0) micrometers, and for example, 3.5 (or about 3.5) micrometers. In case that the thickness of the overcoat layer OC satisfies the above numerical range, it may be advantageous to reduce step differences in the non-display area.

The overcoat layer OC according to some embodiments may be formed through an autoclave process. At this time, the autoclave process may be performed at 40 degrees Celsius (° C.) and 6.5 bar conditions for 5 minutes.

Referring to FIG. 8 and FIG. 13, the first color filter CF1 and the second color filter CF2 may be spaced apart from the opening pattern AM1 in an area in which the opening pattern AM1 is positioned. The first color filter CF1 and the second color filter CF2 may not be positioned in the valley V in which the opening pattern AM1 is located. The valley V in which the opening pattern AM1 is located may be filled with the overcoat layer OC. This is to recognize the opening patterns AM1 and AM2 from the outside and use them as align marks.

A third distance dd3 refers to the distance from the upper surface of the substrate SUB to the upper surface of the overcoat layer OC in the valley V of FIG. 12. A fourth distance dd4 refers to the distance from the upper surface of the substrate SUB to the upper surface of the overcoat layer OC in the valley V of FIG. 13. The difference between the third distance dd3 and the fourth distance dd4 (dd3−dd4) may be 2.5 (or about 2.5) micrometers or less.

Unlike FIG. 12, in case that the first color filter CF1 and the second color filter CF2 are not located in the valley V, or in case that the thickness of the overcoat layer OC is thin unlike some embodiments, the step difference between areas in the valley V may increase. Due to the step difference, the overcoat layer OC may have an uneven upper surface. In case that the protective layer DL is located on such an overcoat layer OC, bubbles may remain between the protective layer DL and the overcoat layer OC, and accordingly, the reliability and display quality of the display device may be degraded.

However, as shown in FIGS. 12 and 13, because the step difference between an area in which the opening patterns AM1 and AM2 are positioned and an area in which they are not positioned in the valley V is reduced through the color filters CF1 and CF2 and the overcoat layer OC, the protective layer and the cover window located on the overcoat layer OC may be stably combined without bubbles.

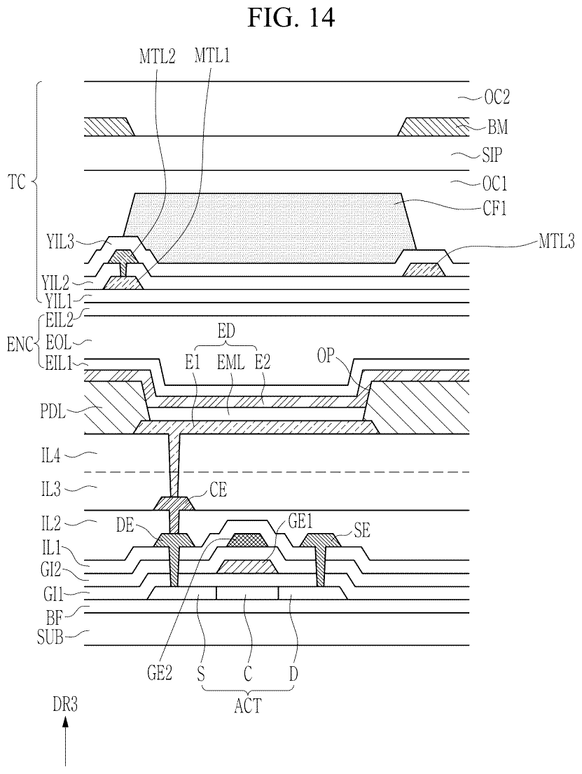

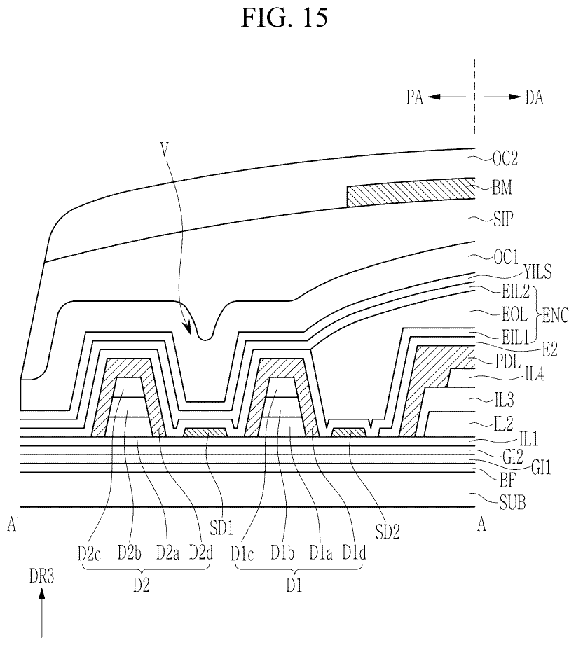

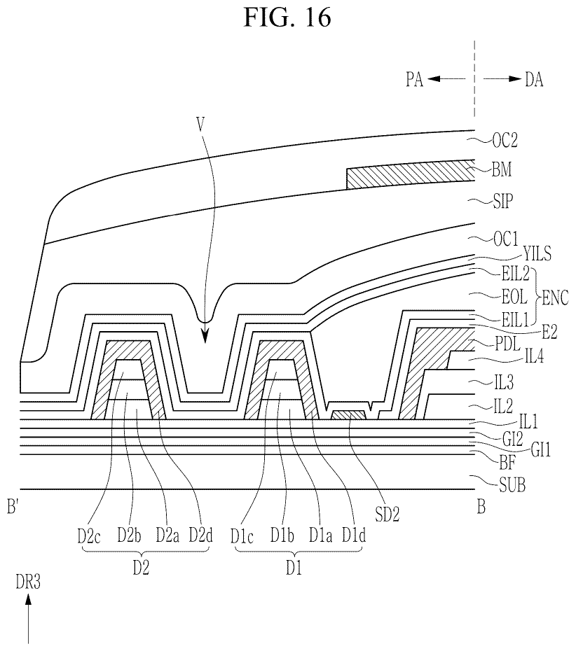

Hereinafter, a display device according to some embodiments will be examined with reference to FIGS. 14 to 16. FIG. 14 is a cross-sectional view of a display area according to some embodiments, and FIGS. 15 and 16 are cross-sectional views of a non-display area according to some embodiments, respectively. Some description of the same components as the aforementioned components may be omitted.

First, referring to FIG. 14, a color filter CF1 may be positioned on the third touch insulating layer YIL3. And a first overcoat layer OC1 may be positioned on the color filter CF1 and the third touch insulating layer YIL3. The first overcoat layer OC1 may include an organic material.

A first touch organic layer SIP may be positioned on the first overcoat layer OC1. The first touch organic layer SIP may be located on the entire front surface of the display area DA. The first touch organic layer SIP is positioned in the display area DA and may extend to the non-display area. The first touch organic layer SIP may have a thickness of 10 (or about 10) micrometers to 20 (or about 20) micrometers, and for example, may have a thickness of 10 (or about 10) micrometers to 15 (or about 15) micrometers. In case that the thickness of the first touch organic layer SIP satisfies the above numerical range, a step difference in a valley of the non-display area to be described later may be relatively reduced.

The first touch organic layer SIP may be manufactured through an inkjet printing process. The first touch organic layer SIP may be formed by applying and drying a first organic material on the entire surface of the substrate SUB. The first organic material may have a viscosity of 10 cPs (or about 10 cPs) to 15 cPs (or about 15 cPs) at room temperature, for example. The first touch organic layer SIP formed of the first organic material may have a refractive index of 1.3 to 1.5 (or about 1.3 to 1.5), and for example, may have a refractive index of 1.499 (or about 1.499). The first touch organic layer SIP may have a modulus of 1.4 GPa (or about 1.4 GPa) to 1.5 GPa (or about 1.5 GPa), and for example, may have a modulus of 1.41 GPa (or about 1.41 GPa). The first touch organic layer SIP may have a strain of 5% to 10% (or about 5% to 10%), and for example, may have a strain value of 6% (or about 6%). The first touch organic layer SIP may have a transmittance of 95% to 100% (or about 95% to 100%) at a wavelength of 565 nm, and for example, may have a transmittance of 99% (or about 99%). In addition, the first touch organic layer SIP may have a haze value of 0.05 to 0.1 (or about 0.05 to 0.1), and for example, may have a haze value of 0.09 (or about 0.09). The yellow index (YI) of the first touch organic layer SIP is 0.3 to 0.4 (or about 0.3 to 0.4), and for example, may be 0.37 (or about 0.37). The surface tension of the first touch organic layer SIP is 20 mN/m (or about 20 mN/m) to 30 mN/m (or about 30 mN/m), and for example, may be 25 mN/m (or about 25 mN/m). The specific gravity of the first touch organic layer SIP may be 1 g/cm³ (or about 1 g/cm³) to 2 g/cm³ (or about 2 g/cm³), and for example, may be 1.01 g/cm³ (or about 1.01 g/cm³). The water contact angle of the first touch organic layer SIP may be 80 degrees to 85 degrees (or about 80 degrees to 85 degrees (°)), and for example, may be 82 degrees (or about 82 degrees (°)). The dielectric constant of the first touch organic layer SIP at room temperature may be 3 to 4 (or about 3 to 4) under 100 kHz conditions, and for example, may be 3.09.

A light blocking layer BM and a second overcoat layer OC2 may be positioned on the first touch organic layer SIP. The light blocking layer BM may overlap with the pixel defining layer PDL and may include a light blocking material. The second overcoat layer OC2 includes an organic material and may be located on the entire front surface of the substrate SUB.

Next, referring to FIG. 15, in a cross-section along A-A′ of FIG. 8, a first overcoat layer OC1, a first touch organic layer SIP, and a second overcoat layer OC2 may be positioned on the first dam D1 and the second dam D2. The first overcoat layer OC1, the first touch organic layer SIP, and the second overcoat layer OC2 may extend from the display area DA to the non-display area PA.

The relatively thick first overcoat layer OC1 and the first touch organic layer SIP may fill a valley V positioned between the first dam D1 and the second dam D2. An upper surface of the first touch organic layer SIP in the non-display area PA may be generally flat. An upper surface of the second overcoat layer OC2 positioned on the upper surface of the first touch organic layer SIP may also be flat.

Next, referring to FIG. 16, in a cross-section along B-B′ of FIG. 8, a first overcoat layer OC1, a first touch organic layer SIP, and a second overcoat layer OC2 may be positioned on the first dam D1 and the second dam D2. The first overcoat layer OC1, the first touch organic layer SIP, and the second overcoat layer OC2 may extend from the display area DA to the non-display area PA.

The relatively thick first overcoat layer OC1 and the first touch organic layer SIP may fill a valley V positioned between the first dam D1 and the second dam D2. An upper surface of the first touch organic layer SIP in the non-display area PA may be generally flat. An upper surface of the second overcoat layer OC2 positioned on the upper surface of the first touch organic layer SIP may also be flat.

A flat upper surface may be provided by the first overcoat layer OC1 and the first touch organic layer SIP in the non-display area PA in which the opening pattern is positioned. Therefore, a protective layer located on the second overcoat layer OC2 may be stably combined, and the reliability of the display device may be relatively improved.

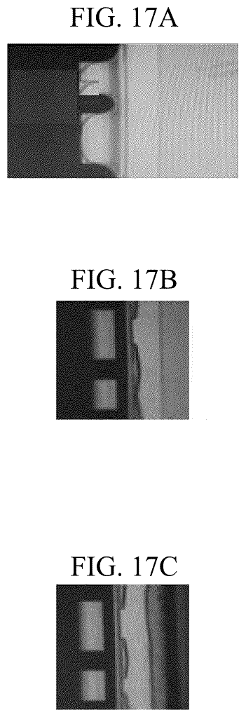

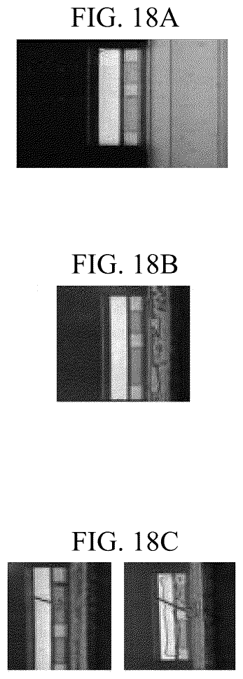

Next, FIG. 17 is an experimental image of a display panel according to some embodiments, and FIG. 18 is an experimental image of a display panel according to a comparative example.

The embodiments of FIG. 17 show a case in which the thickness of the overcoat layer is 3.5 micrometers and the difference between the third distance and the fourth distance is 2.4 micrometers in the structure of FIGS. 12 and 13. The comparative example of FIG. 18 is a case in which the thickness of the overcoat layer is 1.5 micrometers and the difference between the third distance and the fourth distance is 3.58 micrometers in the structure of FIGS. 12 and 13.

FIG. 17 (a) shows fine bubbles, but it was confirmed that bubbles were removed in the portion with the opening pattern after the autoclave process as shown in FIG. 17 (b). Therefore, it was confirmed that no defects occurred as shown in FIG. 17 (c).

On the other hand, FIG. 18 (a) shows bubbles being observed, and it was confirmed that bubbles could penetrate as shown in FIG. 18 (c) due to step differences between areas even after the autoclave process as shown in FIG. 18 (b).

With additional reference to Table 1 in FIGS. 17 and 18, FIG. 17 shows embodiments of Table 1, and FIG. 18 is comparative example 1 of Table 1. In addition, evaluations were also conducted for comparative examples 2 and 3. It was confirmed that the reliability of the display device may be relatively improved without defects only in case that the thickness of the overcoat layer satisfies the range of 3.0 to 4.0 micrometers according to some embodiments, and accordingly the step height satisfies 2.5 micrometers or less.

TABLE 1

| | Overcoat layer | | |
|---|---|---|---|
| | thickness | Step height | Evaluation |
| | (micrometer) | (micrometer) | result |
| Comparative | 1.5 | 3.58 | No effect |
| example 1 | | | |
| Comparative | 1.5 | 3.94 | No effect |
| example 2 | | | (2/4) |
| Comparative | 2.8 | 2.55 | 6% (3/50) |
| example 3 | | | |
| Example | 3.5 | 2.40 | 0% (0/52) |

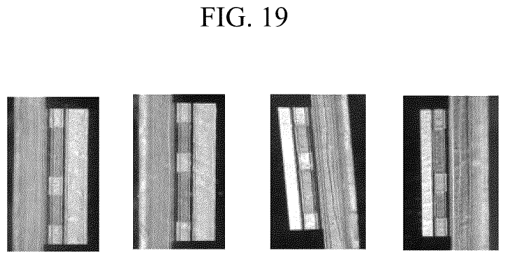

FIG. 19 is an image of a display panel according to some embodiments. FIG. 19 is an image examining whether bubbles occur in embodiments having the structure according to FIGS. 15 and 16. As shown in FIG. 19, in case that the display panel has a stacked structure like FIGS. 15 and 16, it was confirmed that step differences are reduced in areas in which conductive patterns are located, enabling combination with a cover window without bubbles.

Although aspects of some embodiments of the present disclosure have been described in detail above, the scope of embodiments according to the present disclosure is not limited thereto, and various modifications and improvements by those skilled in the art using the concepts of embodiments according to the present disclosure defined in the following claims, and their equivalents, also belong to the scope of embodiments according to the present disclosure.

### DESCRIPTION OF SOME OF THE REFERENCE SYMBOLS

DA: display area
PA: non-display area
SUB: substrate
D1: first dam
D2: second dam
SD1, SD2: conductive pattern
AM1, AM2: opening pattern
OP1, OP2: light blocking opening
BM: light blocking layer
OC: overcoat layer
CF, CF1, CF2: color filter

What is claimed is:

1. A display device comprising:
a substrate including a display area and a non-display area surrounding the display area,
a first dam and a second dam in the non-display area,
a conductive pattern between the first dam and the second dam, and
a light blocking layer on the first dam and the second dam,
wherein the conductive pattern includes an opening pattern between the first dam and the second dam,
the light blocking layer includes a light blocking opening between the first dam and the second dam, and
the opening pattern and the light blocking opening overlap.

2. The display device of claim 1, wherein the opening pattern is spaced apart from the first dam and the second dam.

3. The display device of claim 1, wherein the light blocking opening is spaced apart from the first dam and the second dam.

4. The display device of claim 1, wherein the light blocking opening overlaps at least a portion of the conductive pattern.

5. The display device of claim 1, wherein the light blocking opening surrounds the opening pattern.

6. The display device of claim 1, wherein the light blocking layer overlaps the first dam and the second dam.

7. The display device of claim 1, further comprising a second conductive pattern between the first dam and the display area.

8. The display device of claim 1, wherein the display device further comprises an overcoat layer on the light blocking layer, and the overcoat layer overlaps the opening pattern.

9. The display device of claim 8, wherein the overcoat layer fills a valley between the first dam and the second dam.

10. The display device of claim 1, wherein the light blocking layer includes at least two color filters.

11. The display device of claim 10, wherein the color filter includes a red color filter and a blue color filter, and the red color filter covers the blue color filter.

12. A display device comprising:
a substrate including a display area and a non-display area surrounding the display area,
a first dam and a second dam in the non-display area,
a conductive pattern between the first dam and the second dam,
a first overcoat layer on the first dam and the second dam, and
a first touch organic layer on the first overcoat layer,
wherein the conductive pattern includes an opening pattern between the first dam and the second dam, and
the first overcoat layer and the first touch organic layer overlap a valley between the first dam and the second dam.

13. The display device of claim 12, wherein the display area comprises:
a transistor on the substrate,
a light emitting device electrically connected to the transistor,
an encapsulation layer on the light emitting device,
a sensing electrode on the encapsulation layer, and
a color filter on the sensing electrode,
wherein the first overcoat layer is on the color filter.

14. The display device of claim 13, further comprising:
a light blocking layer on the first touch organic layer, and
a second overcoat layer on the light blocking layer.

15. The display device of claim 14, wherein the second overcoat layer extends to the non-display area and overlaps the valley.

16. The display device of claim 14, wherein the light blocking layer extends to the non-display area and is spaced apart from the valley.

17. The display device of claim 12, wherein the first touch organic layer has a flat upper surface.

18. An electronic device comprising a display device, wherein the display device comprises:
a substrate including a display area and a non-display area surrounding the display area,
a first dam and a second dam in the non-display area,
a conductive pattern between the first dam and the second dam, and
a light blocking layer on the first dam and the second dam,
wherein the conductive pattern includes an opening pattern between the first dam and the second dam,
the light blocking layer includes a light blocking opening between the first dam and the second dam, and
the opening pattern and the light blocking opening overlap.

19. The electronic device of claim 18, wherein the display device further includes an overcoat layer on the light blocking layer, and the overcoat layer overlaps the opening pattern.

20. The electronic device of claim 19, further comprising a protection layer and a cover window on the overcoat layer.
